(19) United States
(12) Patent Application Publication
(10) Pub. No.: US 2008/0132045 A1
(43) Pub. Date: Jun. 5, 2008

(54) LASER-BASED PHOTO-ENHANCED TREATMENT OF DIELECTRIC, SEMICONDUCTOR AND CONDUCTIVE FILMS

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/741,300

(22) Filed: Apr. 27, 2007

Related U.S. Application Data
(63) Continuation-in-part of application No. 11/505,662, filed on Aug. 16, 2006.
Application No. 11/505,662 is a continuation-in-part of application No. 10/982,045, filed on Nov. 5, 2004.

(51) Int. Cl. H01L 21/20; H01L 21/4763; H01L 21/31; C23C 16/00

(52) U.S. Cl. 438/509; 438/660; 438/770; 118/725; 257/E21.495; 257/E21.24; 257/E21.09

(57) ABSTRACT

A metallic, semiconductor, dielectric or oxide layer, such as a thin gate oxide, is formed by supplying a wafer in a processing chamber with thermal energy to heat the wafer and light energy, such as laser light at a selected wavelength, to improve the quality of the resulting layer. The laser light may be focused and/or scanned to control the depth and spatial extent of laser processing.

### CROSS-REFERENCE TO RELATED APPLICATIONS

This application is a continuation-in-part of U.S. application Ser. No. 11/505,662, filed Aug. 16, 2006, which is a continuation-in-part of U.S. application Ser. No. 10/982,045, filed Nov. 4, 2004, both of which are incorporated herein by reference in their entirety.

### BACKGROUND

1. Field of Invention

This invention generally relates to semiconductor manufacturing methods and, more particularly, to a method for treating films during processing.

2. Related Art

Typical semiconductor devices are manufactured by first providing a bulk material, such as Si, Ge, or GaAs, in the form of a semiconductor substrate or wafer. Dopants are then introduced into the substrate to create p- and n-type regions in a process or reaction chamber. The dopants can be introduced using thermal diffusion or ion implantation methods. In the latter method, the implanted ions will initially be distributed interstitially. Thus, to render the doped regions electrically active as donors or acceptors, the ions must be introduced into substitutional lattice sites. This “activation” process is accomplished by heating the bulk wafer, generally in the range of between 600° C. to 1300° C. When using a silicon wafer, for example, a dielectric layer, such as silicon oxide can be “grown” or deposited to provide an electrical interface. Finally a metallization, such as aluminum, is applied using (but not limited to), for example, evaporation, sputtering, chemical vapor deposition (CVD) or atomic layer deposition (ALD).

The quality of thin oxides or dielectrics, such as for gate insulating, is becoming more important in the field of semiconductor devices fabrication. Many broad categories of commercial devices, such as electrically erasable programmable read only memories (EEPROMs), dynamic random access memories (DRAMs), and more recently, even high-speed basic logic functions, depend on the ability to reproduce high quality, very thin oxide layers. High quality dielectrics are needed in such devices to achieve satisfactory devices performance both in terms of speed and longevity.

Present gate insulating layers fall short of the requirements necessary for future devices. Most conventional gate insulating layers are pure silicon oxide SiO₂ oxide films formed by thermal oxidation. Others employ a combination of a high temperature deposited SiO₂ layer on a thermally grown layer.

As semiconductor devices and geometries become smaller and smaller, gate oxides need to be thinner and thinner, e.g., on the order of 15 to 20 Å. However, as the oxide layer becomes thinner, tunneling leakage can become a problem, especially with low quality oxides. With current techniques for oxide growth, the quality of the oxide layer is not sufficient to sustain very thin oxide layers. In general, one way to improve oxide layer quality is to increase the temperature or thermal energy at which the oxide is grown. One problem is that as temperature increases, other dopants may diffuse, which may adversely affect other characteristics of the semiconductor device. On the other hand, when thermal energy, which already has relatively low electron energy, is reduced, the thermally grown oxide exhibits poor qualities, due in part to factors such as poor integration and diffusion effects. Thus, it is difficult to form thin oxide layers with consistent quality and thickness using conventional thermal processes.

Pure SiO₂ layers are unsuitable for devices requiring thin or very thin dielectric or oxide films because their integrity is inadequate when formed, and they suffer from their inherent physical and electrical limitations. SiO₂ layers also suffer from their inability to be manufactured uniformly and defect-free when formed as these thin layers. Additionally, subsequent VLSI processing steps may continue to degrade the already fragile integrity of thin SiO₂ layers. Furthermore, pure SiO₂ layers tend to degrade when exposed to charge injection, by interface generation and charge trapping. As such, pure SiO₂ layers are inadequate as thin films for future scaled technologies.

In tunnel oxides, breakdowns occur because of the trapping of charge in the oxides, thereby gradually raising the electric field across the oxides until the oxides can no longer withstand the induced voltage. Higher quality oxides trap fewer charges over time and will therefore take longer to break down. Thus, higher quality thin film oxides are desired.

Furthermore, usually oxide films are amorphous, i.e., there is a shortened periodicity, such that oxide atoms in close proximity are similar, but as atoms move farther away, their structure becomes unpredictable. The oxide layer may further have unpaired or dangling bonds. If there is an ion or charge, then dangling bonds may be problematic, resulting, for example, in large performance variations between devices.

Thus, it is desirable to make the dangling bonds inactive. One method is to expose the film with the dangling bonds to hydrogen, where the reaction will make the dangling bonds electrically inactive. However, the reaction requires high energy, which can be provided by increasing the temperature or thermal energy. At high temperatures, oxide will grow and would thus undesirably increase the thickness of the “thin” oxide layer.

Therefore, there is a need for methods of forming thin film oxides or dielectrics that overcome the disadvantages of conventional techniques discussed above.

### SUMMARY

According to one aspect of the present invention, light energy, such as a laser beam, is used to irradiate a metallic, semiconductor, dielectric or oxide film before, during and/or after formation of such a film. The additional energy supplied from the laser source allows formation of a high quality thin film at a lower process temperature.

In one embodiment, light having a wavelength between 150 nm and 12 um is used to irradiate a substrate wafer within a process chamber for a time between 1 femtosec and 3600 sec, at a temperature between 0° C. and 1300° C. and a pressure between 0.001 mTorr and 1000 Torr to form a thin dielectric film having a thickness between 1 Å and 10 um. The irradiation may be performed simultaneously with a conventional thin film formation process or can be performed after formation of the film, either in situ or in another chamber. Alternatively, irradiation may be performed prior to the film formation process, either in situ or in another chamber. Process gases used with the irradiation may be any gas or gases used in film formation, such as, but not limited to air, O₂, N₂, HCl, NH₃, N₂H₄, and H₂O.

In one embodiment, the process chamber includes a light beam, such as may be provided by a laser with associated focusing and opto-mechanical scanning capability to illuminate and selectively heat the wafer. The light source is located at the top portion of the chamber and the wafer, and may preferably be placed external to the chamber and access it through an appropriately transparent window. Light sources may include one or more lasers capable of providing a wavelength selected appropriately for the particular process.

In one embodiment, a window is located between the wafer and the light source, where the window can be a filter or a non-filter. A controllable heating source, such as a hot plate, lamps, or susceptor, heats the wafer while process gases are introduced into the chamber. A transport mechanism has the ability to move the wafer into and out of the chamber, as well as within the chamber. Focusing and scanning capability may be located within the chamber, outside the chamber window, or in a combination of locations. The pressure within the process chamber is also adjustable from at least 0.001 mTorr to 1000 Torr. At least one gas inlet/outlet port allows process and other gases to be introduced into and expelled from the chamber. The process chamber can be a single wafer processing chamber or a wafer batch processing chamber.

By using a laser beam in conjunction with thermal energy, the resulting layer can be made as a thin film (e.g., 10 micrometers or less), while maintaining a high quality level. Lower temperatures may be used, which increases the layer quality, such as decreasing adverse diffusion effects, charge trapping, and dangling bonds. Electrical properties of the film may also be improved. For example, the number of unpaired bonds in a silicon-silicon dioxide interface may be greatly reduced. Other advantages of the present invention include reduction of unwanted electric trap/mid-gap density of states, reduction of unwanted Si—OH bonds, and reduction of H₂O in the film.

Laser-based photo-enhancement of thermal curing of other dielectric films such as, for example, organic films, may be accomplished by selective wavelength and focused illumination. As in other examples, the substrate may be held at a lower temperature to eliminate or reduce activation of unwanted effects. Localized curing may be enhanced by selection of wavelengths that preferentially result in, for example, polymer cross-linking, or selective removal of solvents, which are typical required effects in curing of, for example, photo-resists. Such wavelengths may typically be in the infrared range, where absorption due to molecular vibration phonons is high.

Laser-based photo-enhancement of metallic films may be accomplished where the film is thin enough to permit a fraction of the energy to penetrate to the substrate beneath, where absorption may take place and enhance localized heating. In this case, the film must be on the order of some fraction of the skin depth of the laser light, which is determined by the wavelength dependent dielectric coefficient near the metal plasma frequency. Energy that penetrates the metallic film may then be absorbed in the underlying substrate or other layers to provide thermal heating and curing effects restricted to a selected depth, when assisted by bulk thermal heating of the substrate. Focusing the laser beam may provide additional control of the curing process both in lateral spatial extent and selectively in depth. For this type of application, the ultraviolet transparency of metals may require a short wavelength in the UV range.

Laser-based photo-enhanced thermal treatment of thin films may be applied to a wide variety of materials for a variety of effects. For example, ferroelectric or ferromagnetic thin films may be treated to control domain size, anneal, or to selectively provide ferroelectric/ferromagnetic poling in localized areas and depth. Additionally, ionic charge density and distribution in a layer may be selectively modified.

The selection of wavelength and feature size and depth may again be determined by the absorption property of the film and/or substrate and film thickness.

These and other features and advantages of the present invention will be more readily apparent from the detailed description of the preferred embodiments set forth below taken in conjunction with the accompanying drawings.

### BRIEF DESCRIPTION OF THE DRAWINGS

FIG. 1 is a flow chart of one embodiment of the present disclosure for forming a dielectric layer on a wafer.

FIG. 2 is a schematic illustration of a side view of an embodiment of a semiconductor wafer processing system for performing the process of FIG. 1.

FIG. 3A is an illustration of a laser beam focused at an interface at a selected depth below the substrate surface, in accordance with an embodiment of the disclosure.

FIG. 3B illustrates the change in laser beam intensity with depth of the laser beam of FIG. 3A, in accordance with an embodiment of the disclosure.

Embodiments of the present invention and their advantages are best understood by referring to the detailed description that follows. It should be appreciated that like reference numerals are used to identify like elements illustrated in one or more of the figures.

### DETAILED DESCRIPTION

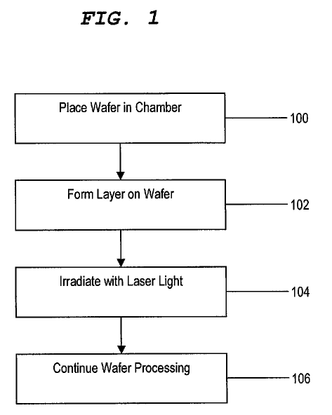

FIG. 1 is a flow chart showing one embodiment of the present invention for forming dielectric films. In step 100, a semiconductor wafer is placed into a process chamber. The wafer can be at different stages of processing, depending on the type of film to be formed on the wafer.

In step 102, a layer, such as, for example, a gate insulating film, is formed on the wafer, such as by introducing one or more process gases into the process chamber. The process gases are used for formation of a layer on the wafer. The formation process can be growth or deposition of the layer by, for example, chemical vapor deposition (CVD), physical vapor deposition (PVD), or spin coating using a liquid source. Suitable process gases include, but are not limited to, air, O₂, N₂, HCl, NH₃, and H₂O.

Pressure and temperature within the chamber are adjusted depending on the process and system parameters. For example, the pressure may range from 0.001 mTorr to 1000 Torr, and temperature may range from 0° C. to 1300° C. In one embodiment, the temperature is less than 800° C. Because the processes of growing or depositing various layer materials are well known, specific process parameters will not be given. It should be noted that those skilled in the art will use appropriate process parameters depending on the characteristics needed for the film. One important feature of the present invention is that the temperature does not need to be increased significantly during formation of a thin film to increase the quality of the film.

In step 104, the wafer is irradiated with laser light of a selected photon energy. In one embodiment, the irradiation is performed during formation of the dielectric layer. In another embodiment, the irradiation is performed after formation of the layer or film, such as between film formation cycles for curing. Thus, the laser source can be turned off and on during different periods of the film formation and for different durations. For example, the laser source can be turned on continuously from the beginning of the film formation process to the end of the process or during any one or more periods in between.

Further, in one embodiment, the irradiation in step 104 can be performed in situ. In other embodiments, the irradiation is performed in a separate process chamber, such as processes in which the wafer is moved from the deposition process chamber to another chamber, either associated with the same machine or in a separate machine. In one embodiment, the light has a wavelength between 150 nm and 12 μm in the ultraviolet (UV) to infrared (IR) range. UV light, especially, has relatively high energy, i.e., corresponding to approximately 3 eV and higher. After the layer is formed in steps 102 and 104, processing continues in step 106, as needed for manufacturing the semiconductor device.

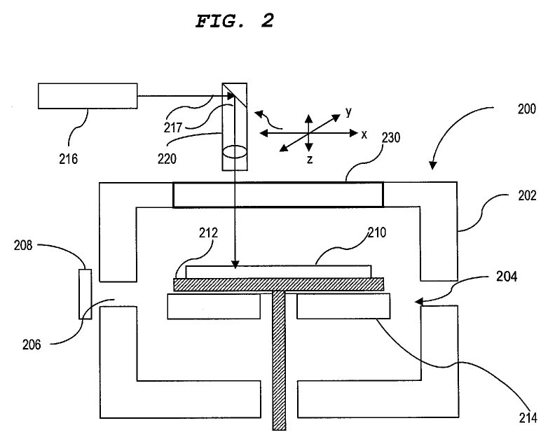

FIG. 2 shows a simplified cross-sectional view of a portion of a process reactor 200 in accordance with one embodiment of the present invention. Process reactor 200 includes a shell 202, which can be made of aluminum or other suitable metal that substantially encloses a process chamber 204, such as a load lock chamber. Process chamber 204 may be formed from a process tube, such as made from quartz, silicon carbide, Al₂O₃, or other suitable material. To conduct a process, process chamber 204 should be capable of being pressurized. Typically, chamber 204 should be able to withstand internal pressures of about 0.001 mTorr to 1000 Torr, preferably between about 0.1 Torr and about 760 Torr. An opening 206 to process chamber 204 is sealable by a gate valve 208. Gate valve 208 is operable to seal opening 206, such as during wafer processing, and to uncover opening 206, such as during wafer transfer into and out of chamber 204. Robot assemblies or other mechanisms (not shown) can be used to transfer a wafer 210, such as from a wafer cassette, to and from the process chamber.

Located within process chamber 204 is a wafer support 212 that supports wafer 210 during processing. Wafer support 212 can be fixed or movable to position the wafer up and down or rotate the wafer within the process chamber. Wafer support 212 can be a plate (as shown), individual standoffs, or any other suitable support. A heat source 214 is also contained within process chamber, such as below wafer 210. Heat source can be any suitable wafer heating source, such as a susceptor, hot plate, or lamps. Lamps may be a single lamp or an array of individual lamps, positioned at distances both from the wafer and from each other to uniformly heat the overlying wafer.

In one embodiment, a laser source 216 is located external to chamber 200 for providing light energy, which may be UV, visible or infrared energy, to the wafer during processing, as described above. Suitable laser sources 216 in the UV include nitrogen, He—Cd, cerium doped strontium (or calcium) fluoride, gallium nitride, metal vapor, and free electron lasers. A large variety of lasers operational in the visible, near and mid-infrared are well known in the art. The choice of laser source depends on various factors, including desired wavelength and power.

The wavelength or frequency of the light can be adjusted, based on various factors, such as the process and type of layer formed. In one embodiment, the wavelength of the light is between 150 nm and 12 μm. In order to maximize the effectiveness of light energy incident on wafer 210, a beam control 220 may direct the laser beam through a window 230 that is transparent to the selected wavelength. Accordingly, window 230 can be a filtering window or a non-filtering window, made of materials such as, but not limited to, quartz and ZnSe, selected for transparency at the laser wavelength.

Beam control 220 provides scanning and focusing optics to position and concentrate the light energy effectively at a selected depth and area of wafer 210. Beam control 220 may be configured to translate parallel to the surface of wafer 210, i.e., x-y, orient at an angle θ (not shown) to the wafer surface, and translate one or more component optical elements therein to control the focal point at a selected depth, i.e., z motion. Provided window 230 is transparent, the wavelength may be selected on the basis of the transparency and absorption of the grown layer and the absorption of the wafer 210 underlying the grown layer. Details of beam control 220 to provide light scanning and focusing in one embodiment are discussed in detail in commonly-owned U.S. application Ser. No. 11/689,419, filed Mar. 21, 2007, which is incorporated herein in its entirety.

Various process chambers and processes can be used with the present invention. For example, the process chamber can be a single wafer chamber for rapid thermal processing or multiple wafer systems. Processing can be thermal annealing, dopant diffusion, thermal oxidation, nitridation, chemical vapor deposition, and similar processes, in which a processing step forms a thin dielectric layer where light energy used during layer formation improves the quality of the resulting layer.

One advantage of using laser energy is the high energy levels as compared to thermal energy from conventional heat sources, such as hot plates and susceptors. Furthermore, a narrow laser wavelength at higher photon energy (i.e., shorter wavelength) may be more efficient than a broad spectrum thermal source because the absorption of energy can be finely tuned to a resonance absorption wavelength of the material and optimized by focusing in a localized depth region of wafer 210 where the layer is grown. Because thermal energy has low efficiency, when it is converted to electron energy, the energy level is low. However, light energy, within the visible light spectrum, corresponds to more than 1 eV, while light in the UV spectrum corresponds to 3 eV or higher. Thus, high photon energy in the form of wavelength specific laser light can be supplied to the wafer during processing, in addition to thermal energy. The laser light does not cause growth of the layer, as may be the case when only thermal energy at higher temperatures is employed, but rather improves the quality of such a layer. Additional advantages include reduction of charge trapping, reduction or elimination of dangling bonds, and improvement of electrical properties of the resulting device.

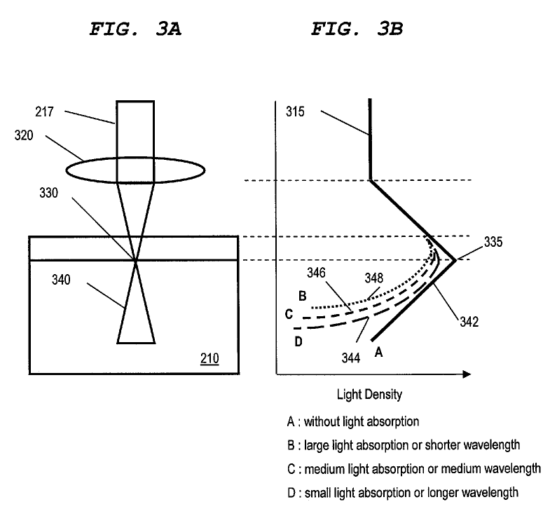

FIG. 3A is an illustration of a laser beam focused for curing films at a selective depth according to one embodiment. Referring to FIG. 3A, a collimated laser beam 217 is focused by a lens 320 included in beam controller 220 at a selected depth 330 below the surface of substrate 210. The beam density reaches substantially maximum value at this depth. The beam becomes a divergent beam 340 beyond this point, and the beam density correspondingly decreases.

Referring to FIG. 3B, the collimated beam 217 has a constant aperture and light density 315 up to the lens. Lens 320 may be representative of a single lens or a system of lenses. Lens 320 focuses the beam at selected depth 330 of substrate 210, and the corresponding light density reaches a maximum density 335 at selected depth 330.

Four examples of light propagation conditions may be considered to illustrate the results of light propagation and processing effects in substrate 210. Case A illustrates the dependence of light beam energy density as a function of propagation depth into substrate 210 when substrate 210 is substantially transparent, i.e., there is substantially no light absorption. The dependence of light density 342 on depth is strictly determined by spatial dispersion of divergent beam 340 due to the focal properties of lens 320 and the index of refraction (being substantially real and positive, i.e., without absorption) of substrate 210, and all layers therein. As the substrate material is transparent and non-absorbing, there is substantially no thermal heating and no optical interaction between the beam and substrate 210 to cause any process effects to occur.

Case B illustrates the dependence of light beam energy density as a function of propagation depth into substrate 210 when the substrate material is highly absorptive. This may occur as a result of a combination of layers of the substrate having a complex index of refraction (i.e., having a real and an imaginary component) at the selected wavelength of light beam 217, such that the wavelength dependent index of refraction is complex, which may also occur for a wavelength that is shorter than for cases described below. Those of ordinary skill in the art will recognize that a larger imaginary component of index of refraction will result in a larger rate of absorption. In this case, the light energy is rapidly absorbed by the substrate in a relatively short depth of penetration. Therefore, light beam density 348 of divergent beam 340 decreases rapidly with penetration depth, and processing effects due to thermal heating resulting from the absorption will occur preferentially in a short range of penetration, substantially near the depth corresponding to the focal point 330.

Case C illustrates the dependence of light beam density 346 as a function of propagation depth into substrate 210 when the substrate material has medium absorption, as a result of wavelength selection, which may be a somewhat longer wavelength than in Case B. In this case light beam density 346 decreases more gradually with penetration depth, and correspondingly penetrates deeper into substrate 210. Therefore, two effects may occur: (1) since absorption is somewhat less than in Case B, heating effects may occur more slowly, and therefore more processing time may be required; (2) since the light density decreases more slowly, the energy density remains relatively high to a greater depth, so that processing effects may occur deeper into substrate 210.

Case D illustrates the dependence of light beam density 344 as a function of propagation depth into substrate 210 when layers of substrate 210 have relatively low absorption, which may also occur at relatively longer wavelengths than in Cases B and C. In this case, light density 344 decreases more gradually and penetrates more deeply into substrate 210.

Because absorption effects are known to typically obey an exponentially decaying dependence with propagation distance, Cases B, C and D are shown with a rate of decreasing light density that is always greater than the decrease due purely to spatial dispersion of the beam due to focal properties in the absence of absorption.

It is well known to those of ordinary skill in the art that an optical system of a given aperture and with a longer focal length will have a larger diffraction limited spot size at the focal point than will an optical system of the same aperture and shorter focal length. This will limit the light beam power and energy density at the focal point to a lower density relative to shorter focal length systems. Thus, a shorter focal length system of the same aperture will have a higher focal point maximum beam power and energy density. In addition, shorter focal point optical systems will also have a more divergent beam, such that the range of depth may be more restricted at which thermally or optically induced processing effects may take place.

The above-described embodiments of the present invention are merely meant to be illustrative and not limiting. For example, dielectric or oxide films are discussed here; however, other layers formed during various forms of deposition processing may also benefit from irradiation with a laser light source according to the present invention. It will thus be obvious to those skilled in the art that various changes and modifications may be made without departing from this invention in its broader aspects. Therefore, the appended claims encompass all such changes and modifications as fall within the true spirit and scope of this invention.

What is claimed is:

1. A method for processing substrate wafers, comprising:
providing a substrate in a processing chamber;
providing a process gas within the processing chamber;
forming a material layer over the substrate; and
irradiating the substrate with laser light to improve the quality of the material layer.

2. The method of claim 1, further comprising heating the substrate during formation of a material layer.

3. The method of claim 1, wherein the laser light has a wavelength between approximately 150 nanometers and 12 micrometers.

4. The method of claim 1, wherein the material layer is selected from a group consisting of an oxide layer, an organic layer, a semiconductor layer, and a conductive layer.

5. The method of claim 1, wherein the material layer is a thin oxide having a thickness between approximately 1 Å and 10 micrometers.

6. The method of claim 1, wherein the irradiation is by a laser source located above the substrate.

7. The method of claim 2, wherein the heating is thermal heating.

8. The method of claim 2, wherein the heating grows the layer.

9. The method of claim 1, wherein the irradiating is during formation of the layer.

10. The method of claim 1, wherein the irradiating is after formation of the layer.

11. The method of claim 1, wherein the irradiating is before formation of the layer.

12. The method of claim 1, further comprising moving the substrate into a second processing chamber after formation of the layer and prior to irradiating.

13. The method of claim 2, wherein the heating and irradiating are in situ.

14. The method of claim 1, wherein the laser beam is focused at the substrate surface or a selected depth below the surface of the layer.

15. The method of claim 1, wherein the laser beam is configured to scan across at least a portion of the wafer.

16. A wafer processing system comprising:
a process chamber;
a gas distribution system configured to introduce a process gas into the chamber;
a wafer support for supporting a wafer during processing;
a heating element positioned below the wafer;
an irradiating laser source positioned above the wafer; and
a focusing system positioned above the wafer.

17. The processing system of claim 16, wherein the focusing system is configured to scan a laser beam across at least a portion of the wafer.

18. The processing system of claim 16, wherein the process gas is selected to form a layer on the wafer.

19. The processing system of claim 16, wherein the laser wavelength is between 150 nanometers and 12 micrometers.

20. The processing system of claim 16, wherein the laser source comprises a plurality of lasers.

21. The processing system of claim 16, wherein the heating element is a thermal heating element.

22. The processing system of claim 16, further comprising a window between the wafer and the irradiating laser source.

23. The processing system of claim 22, wherein the window is a filtering window.

24. The processing system of claim 25, wherein the heating element and the irradiating light source are configured to both be on during formation of a layer on the wafer.
